(19) United States
(12) Patent Application Publication
(10) Pub. No.: US 2025/0360528 A1
(43) Pub. Date: Nov. 27, 2025

(54) RECORDING MEDIUM, INFORMATION PROCESSING METHOD, AND INFORMATION PROCESSING DEVICE

(71) Applicant: Tokyo Electron Limited, Tokyo (JP)

(72) Inventor: Masayuki OGAWA, Koshi City (JP)

(73) Assignee: Tokyo Electron Limited, Tokyo (JP)

(21) Appl. No.: 19/216,881

(22) Filed: May 23, 2025

(30) Foreign Application Priority Data
May 27, 2024 (JP) 2024-085787

(51) Int. Cl. B05B 12/08; B05C 11/10; G06T 7/00; G06V 10/764

(52) U.S. Cl. CPC B05B 12/084; B05C 11/1015; B05C 11/1026; G06T 7/0006; G06V 10/764

(57) ABSTRACT

A computer-readable recording medium having stored thereon a computer program that, in response to execution, causes a computer to perform a method. The method includes acquiring a moving image of a discharger of a substrate processing apparatus configured to discharge a liquid to a substrate as a processing target; inputting a frame image included in the acquired moving image into a learning model that has been machine learning-trained to receive an image of the discharger as an input and output information related to a discharge state of the liquid from the discharger; acquiring the information related to the discharge state output by the learning model; and determining appropriateness of the discharge of the liquid based on the acquired information.

### CROSS-REFERENCE TO RELATED APPLICATION

This application claims the benefit of Japanese Patent Application No. 2024-085787 filed on May 27, 2024, the entire disclosure of which is incorporated herein by reference.

### TECHNICAL FIELD

The various aspects and embodiments described herein pertain generally to a recording medium, an information processing method, and an information processing device.

### BACKGROUND

Patent document 1 proposes a substrate processing method that includes a holding process of carrying a substrate into a chamber and holding it, a supply process of supplying a fluid to the substrate inside the chamber, an imaging process of sequentially imaging the inside of the chamber with a camera to acquire image data, a condition setting process of identifying a monitoring target from multiple monitoring target candidates inside the chamber and changing image conditions based on the monitoring target, and a monitoring process of performing a monitoring processing on the monitoring target based on the image data having the image conditions corresponding to the monitoring target.
Patent Document 1: Japanese Patent-Laid open Publication No. 2021-190511

### SUMMARY

In an exemplary embodiment, there is provided a computer-readable recording medium having stored thereon a computer program that, in response to execution, causes a computer to perform a method. The method includes acquiring a moving image of a discharger of a substrate processing apparatus configured to discharge a liquid to a substrate as a processing target; inputting a frame image included in the acquired moving image into a learning model that has been machine learning-trained to receive an image of the discharger as an input and output information related to a discharge state of the liquid from the discharger; acquiring the information related to the discharge state output by the learning model; and determining appropriateness of the discharge of the liquid based on the acquired information.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic diagram for describing a configuration example of a substrate processing apparatus according to an exemplary embodiment;

FIG. 2 is a schematic diagram for describing an outline of an information processing system according to the exemplary embodiment;

FIG. 3 is a block diagram illustrating a configuration example of an information processing device according to the exemplary embodiment;

FIG. 4 is a schematic diagram for describing a configuration example of a learning model used by the information processing device according to the exemplary embodiment;

FIG. 5 is a schematic diagram illustrating an example of a discharge state;

FIG. 6 is a flowchart showing an example sequence of a discharge state determination processing performed by the information processing device according to the exemplary embodiment;

FIG. 7 is a flowchart showing an example sequence of an abnormality determination processing performed by the information processing device according to the exemplary embodiment;

FIG. 8 is a flowchart showing an example sequence of the abnormality determination processing performed by the information processing device according to the exemplary embodiment;

FIG. 9 is a schematic diagram illustrating an example of a warning screen displayed by the information processing device according to the exemplary embodiment;

FIG. 10 is a schematic diagram illustrating an example of information display by the information processing device according to the exemplary embodiment;

FIG. 11 is a flowchart showing an example sequence of an abnormality determination processing performed by the information processing device according to a first modification example; and

FIG. 12 is a diagram showing an example of a warning screen displayed by the information processing device according to a second modification example.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Specific examples of an information processing system according to exemplary embodiments of the present disclosure will be described below with reference to the accompanying drawings. Here, it should be noted that the present disclosure is not limited to these exemplary embodiments, but is defined by the scope of the claims, and it is intended that all modifications within the meaning and scope equivalent to the scope of the claims are included.

### <System Configuration>

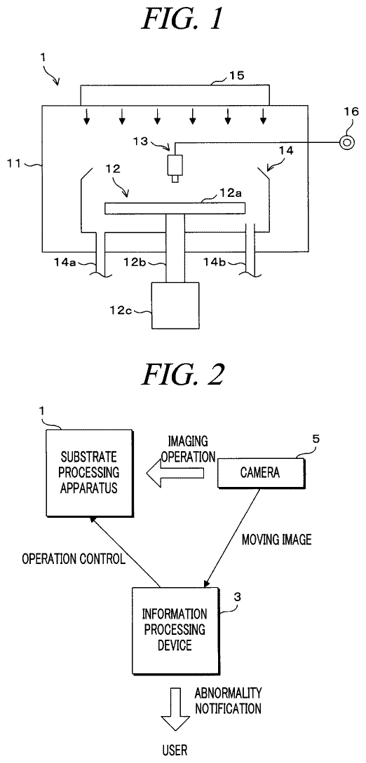

FIG. 1 is a schematic diagram illustrating a configuration example of a substrate processing apparatus 1 according to an exemplary embodiment. The substrate processing apparatus 1 according to the present exemplary embodiment is an apparatus that performs a substrate processing, so-called wet etching, of processing a substrate (for example, a wafer on which an oxide film or nitride film is formed) as a processing target into a required shape by supplying the film with a chemical liquid that dissolves the film, while rotating the substrate. The substrate processing apparatus 1 according to the exemplary embodiment includes a chamber 11, a substrate holding mechanism 12, a discharger 13, a recovery cup 14, and so forth.

The chamber 11 is a hermetically sealed reaction vessel, and houses therein the substrate holding mechanism 12, the discharger 13, the recovery cup 14, and the like. A fan filter unit (FFU) 15 is provided on a ceiling of the chamber 11. The FFU 15 forms a downflow inside the chamber 11.

The substrate holding mechanism 12 has a holder 12a, a supporting column 12b, and a driver 12c. The holder 12a is of, for example, a disk shape, and holds a substrate (wafer) as a processing target horizontally on the disk. The supporting column 12b is a cylindrical member connected to a central portion of a bottom surface of the holder 12a and extending in a vertical direction (up-and-down direction in FIG. 1) and is configured to support the holder 12a horizontally. A lower end of the supporting column 12b is connected to the driver 12c and is rotatably supported by the driver 12c. The driver 12c has a prime mover such as a motor and is configured to rotate the supporting column 12b around its axis. With this configuration, the substrate holding mechanism 12 may rotate the holder 12a supported by the supporting column 12b by rotating the supporting column 12b with the driver 12c, thus allowing the substrate held by the holder 12a to be rotated.

The discharger 13 is configured to discharge a liquid such as a chemical liquid or a cleaning liquid onto the substrate held by the substrate holding mechanism 12. By way of example, dilute hydrofluoric acid is used as the chemical liquid, and pure water is used as the cleaning liquid. However, the liquids discharged by the discharger 13 are not limited thereto. The discharger 13 is connected via, for example, a tube-shaped liquid supply path to a liquid supply source 16 provided outside the chamber 11 and is configured to discharge the liquid supplied from the supply source 16 onto the substrate. Further, the discharger 13 is connected to a non-illustrated driving mechanism and is movable horizontally between a central portion and a peripheral portion of the substrate. By combining the rotation of the substrate by the substrate holding mechanism 12 and the horizontal movement of the discharger 13 by the driving mechanism, the substrate processing apparatus 1 is capable of discharging the liquid from the discharger 13 to an appropriate position on the processing target substrate.

The recovery cup 14 is configured to surround the holder 12a of the substrate holding mechanism 12 and serves to collect the liquid scattered from the substrate due to the rotation of the holder 12a. A drain port 14a is provided at a bottom of the recovery cup 14, and the liquid collected by the recovery cup 14 is drained from the drain port 14a to the outside of the chamber 11. An exhaust port 14b is provided at the bottom of the recovery cup 14, and a gas supplied from the FFU 15 is exhausted from the exhaust port 14b to the outside of the chamber 11.

The substrate processing apparatus 1 shown in FIG. 1 has a configuration in which only one discharger 13 for discharging the liquid is provided. The substrate processing apparatus 1 is capable of selectively discharging either the chemical liquid for performing a dissolving processing for the substrate or the cleaning liquid for cleaning the substrate by switching the chemical liquid and the cleaning liquid in the supply source 16. However, the substrate processing apparatus 1 may have a configuration including a plurality of dischargers 13. The substrate processing apparatus 1 may be equipped with, for example, a discharger 13 for discharging the chemical liquid and a discharger 13 for discharging the cleaning liquid.

FIG. 2 is a schematic diagram illustrating an outline of an information processing system according to the exemplary embodiment. The information processing system according to the exemplary embodiment includes the above-described substrate processing apparatus 1, an information processing device 3, and a camera 5. The camera 5 includes an imaging element such as a charge coupled device (CCD) or a complementary metal oxide semiconductor (CMOS) and is capable of performing so-called moving image recording by performing imaging operations several tens of times per second. The camera 5 is disposed, for example, inside the chamber 11 of the substrate processing apparatus 1, and is configured to image the discharger 13 during the substrate processing. The camera 5 sends moving image data obtained by this imaging operation to the information processing device 3. The moving image data is, for example, data in which multiple still images (frame images) are arranged in time series. The camera 5 may be, for example, a device belonging to the substrate processing apparatus 1, or may be provided as a separate device from the substrate processing apparatus 1.

The information processing device 3 is a device configured to control and monitor the substrate processing by the substrate processing apparatus 1. In the present exemplary embodiment, the information processing device 3 is provided as a separate device from the substrate processing apparatus 1, but it is not limited thereto and may be configured as a single structure with the substrate processing apparatus 1. The information processing device 3 is connected to the substrate processing apparatus 1 and the camera 5 via, for example, a communication cable, and can transceive data between the substrate processing apparatus 1 and the camera 5. The information processing device 3 receives the moving image data of the discharger 13 transmitted by the camera 5 and makes a determination on a state related to a liquid discharge from the discharger 13 based on the received moving image data. The information processing device 3 controls the operation of the substrate processing apparatus 1 according to the determined state of the liquid discharge. Further, the information processing device 3 determines whether the substrate processing is normal or abnormal based on the determined state of the liquid discharge, and if there is an abnormality, notifies a user of the abnormality by outputting a message or a sound.

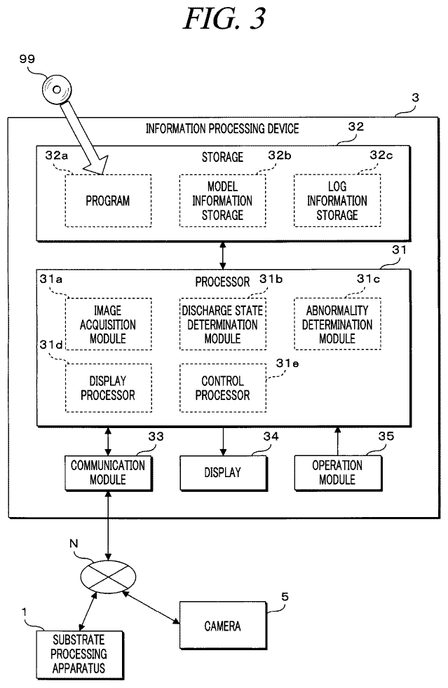

FIG. 3 is a block diagram illustrating a configuration example of the information processing device 3 according to the present exemplary embodiment. The information processing device 3 according to the present exemplary embodiment may be implemented by installing a preset application program or the like in a general-purpose information processing device such as, but not limited to, a personal computer or a server computer. The information processing device 3 according to the exemplary embodiment includes a processor 31, a storage 32, a communication module 33, a display 34, an operation module 35, and the like. In the present exemplary embodiment, the processing is performed by the single information processing device 3. However, the processing of the information processing device 3 may be performed by a plurality of devices in a distributed manner.

The processor 31 is composed of a processing module such as a central processing unit (CPU), a micro-processing unit (MPU), a graphics processing unit (GPU), or a quantum processor, and also includes a read only memory (ROM), a random access memory (RAM), and the like. The processor 31 reads and executes a program 32a stored in the storage 32, thereby performing various types of processes such as a process of determining the discharge state of the discharger 13 of the substrate processing apparatus 1 based on the moving image acquired from the camera 5, a process of controlling the operation of the substrate processing apparatus 1 based on the determined discharge state, and a process of notifying the abnormality of the substrate processing based on the determined discharge state.

The storage 32 is composed of a large-capacity storage device such as, but not limited to, a hard disk or a solid state drive (SSD). The storage 32 stores various types of programs to be executed by the processor 31, and various data necessary for the processing of the processor 31. In the present exemplary embodiment, the storage 32 stores the program 32a to be executed by the processor 31. The storage 32 is provided with a model information storage 32b that stores information related to a learning model that has been machine learning-trained to be used by the information processing device 3, and a log information storage 32c that stores log information related to the substrate processing of the substrate processing apparatus 1.

In the present exemplary embodiment, the program (a computer program or a program product) 32a is provided in a form recorded on a recording medium 99 such as a memory card or an optical disk, and the information processing device 3 reads the program 32a from the recording medium 99 and stores it in the storage 32. However, the program 32a may be written into the storage 32 in the manufacturing stage of the information processing device 3, for example. As another example, the information processing device 3 may acquire, through communication, the program 32a transmitted by a remote server device or the like. By way of example, a write device may read the program 32a recorded on the recording medium 99 and write it into the storage 32 of the information processing device 3. The program 32a may be provided in a form to be transmitted via a network, or may be provided in a form recorded on the recording medium 99.

The model information storage 32b stores information related to the learning model that has been machine-learning trained. The information related to the learning model may include, by way of example, information indicating a configuration of the learning model, information such as internal parameter values determined by the machine learning, and the like.

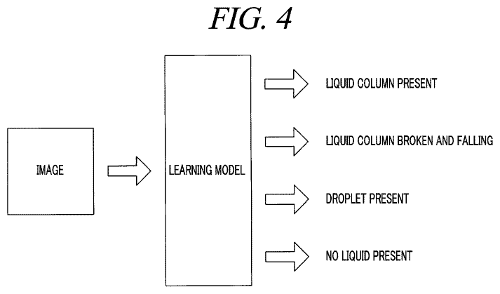

FIG. 4 is a schematic diagram illustrating a configuration example of the learning model which is used by the information processing device 3 according to the exemplary embodiment. The learning model according to the exemplary embodiment is a learning model that has been subjected to machine learning in advance to receive an image (still image) of the discharger 13 of the substrate processing apparatus 1 as an input and output information related to the discharge state of the liquid by the discharger 13. The learning model according to the exemplary embodiment may adopt a configuration such as a convolutional neural network (CNN) or a deep neural network (DNN) but is not limited thereto and may have any of various configurations.

In the present exemplary embodiment, the discharge state of the liquid by the discharger 13 is classified into four states: “liquid column present,” “liquid column broken and falling,” “droplet present,” and “no liquid present.” The learning model outputs four values corresponding to these four states, and the information processing device 3 may determine the state corresponding to the largest of the four values output by the learning model as a discharge state at that moment. However, the discharge state is not limited to the above four states, and states other than the aforementioned four states may be adopted, or three or less states or five or more states may be adopted.

In order to perform the machine learning to generate the learning model, the images of the discharger 13 of the substrate processing apparatus 1 discharging the liquid are collected in advance by the camera 5, and an operation (annotation operation) of labeling the discharge state of the discharger 13 shown in the collected images as one of the aforementioned four states is performed in advance by a designer or the like. The information processing device 3 may generate the learning model by performing a so-called supervised machine learning processing based on the training data in which the image of the discharger 13 and the label of the discharge state are matched. The information processing device 3 stores the information related to the learning model generated by the machine learning in the model information storage 32b.

Further, in the present exemplary embodiment, the information related to the learning model is stored in the information processing device 3, and the processing by the learning model is performed by the information processing device 3. However, the exemplary embodiment is not limited thereto. The information related to the learning model may be stored in a device different from the information processing device 3, and this device may perform the processing by the learning model, and the information processing device 3 may acquire the processing result from this device. Also, the machine learning processing for the learning model may be performed by the information processing device 3 or may be performed by a device different from the information processing device 3.

The log information storage 32c stores therein various information obtained in accompaniment with the substrate processing performed by the substrate processing apparatus 1, while matching them with, for example, date and time, identification information of the substrate processing, and the like. The information stored in the log information storage 32c includes, for example, a moving image acquired by the camera 5, a frame image extracted from this moving image, a discharge state determined by the learning model based on the frame image, presence or absence of an abnormality in the substrate processing based on the discharge state, or control contents related to the substrate processing performed based on the discharge state.

The communication module 33 transmits and receives data between the substrate processing apparatus 1 and the camera 5 via, for example, a wired or wireless network N. In the present exemplary embodiment, the communication module 33 receives the data of the moving image transmitted from the camera 5 and sends it to the processor 31. Also, the communication module 33 receives control information including operation settings and instructions related to the substrate processing from the processor 31 and controls the operation of the substrate processing apparatus 1 by transmitting the received control information to the substrate processing apparatus 1.

The display 34 is composed of a liquid crystal display or the like, and displays various images and characters based on the processing of the processor 31. The display 34 displays various information such as the image (moving image or still image) captured by the camera 5, the information related to the discharge state determined by the learning model, the notification of the abnormality in the substrate processing, and the like.

The operation module 35 receives a user's operation and notifies the processor 31 of the received operation. By way example, the operation module 35 receives a user's operation through an input device such as a mechanical button or a touch panel provided on a surface of the display 34. Further, the operation module 35 may be, for example, an input device such as a mouse or keyboard, and these input devices may be configured to be provided separately from the information processing device 3.

Further, the storage 32 may be an external storage device connected to the information processing device 3. The information processing device 3 may be a multi-computer including a plurality of computers, or may be a virtual machine virtually constructed by software. Further, the information processing device 3 is not limited to the above configuration, and may include, by way of example, a reading module configured to read information stored in a portable recording medium, or may not include, for example, the display 34 and the operation module 35.

In the information processing device 3 according to the present exemplary embodiment, the processor 31 reads and executes the program 32a stored in the storage 32, thereby causing an image acquisition module 31a, a discharge state determination module 31b, an abnormality determination module 31c, a display processor 31d, a control processor 31e, and the like to be implemented in the processor 31 as software functional modules. In the drawings, functional modules that perform a processing related to the discharge state of the discharger 13 of the substrate processing apparatus 1 are shown as functional modules of the processor 31, and functional modules related to a processing other than this are omitted.

The image acquisition module 31a performs a processing of acquiring the image data of the discharger 13 of the substrate processing apparatus 1 obtained by the camera 5 by communicating with the camera 5 through the communication module 33. In the present exemplary embodiment, the camera 5 is configured to acquire a moving image by performing imaging operations about several tens of times per second. The image data obtained by the image acquisition module 31a may be in the form of a moving image or may be in the form of a still image (frame image) included in the moving image. The image acquisition module 31a repeatedly performs the acquisition of the image from the camera 5, adds information such as image acquisition date and time and identification information of the processing target substrate to the image acquired from the camera 5, and stores it in the log information storage 32c. Further, the image acquisition module 31a repeatedly performs the acquisition of the image from the camera 5 while the substrate processing is being performed, thereby obtaining time-series still images of the discharger 13.

The discharge state determination module 31b performs a processing of determining a discharge state of the discharger 13 of the substrate processing apparatus 1 based on the images (frame images included in the moving image) acquired by the image acquisition module 31a. As described above, the discharge state determination module 31b in the present exemplary embodiment determines the discharge state by using the learning model stored in the model information storage 32b. The discharge state determination module 31b inputs the image of the discharger 13 acquired by the image acquisition module 31a into the learning model and acquires four values output by the learning model. The discharge state determination module 31b compares the four values acquired from the learning model and determines whether the discharge state of the discharger 13 is “liquid column present,” “liquid column broken and falling,” “droplet present,” or “no liquid present.” The discharge state determination module 31b stores the information related to the determined discharge state in the log information storage 32c in association with the original image. Also, the discharge state determination module 31b may input a plurality of images acquired in time series from the camera 5 by the image acquisition module 31a into the learning model in time series to determine the discharge state and obtain a determination result of the time-series discharge states.

The abnormality determination module 31c performs determination on normality/abnormality regarding the substrate processing performed by the substrate processing apparatus 1 based on the determination result of the discharge state obtained by the discharge state determination module 31b. In the present exemplary embodiment, based on the plurality of time-series discharge states determined by the discharge state determination module 31b based on the plurality of images acquired in time series by the image acquisition module 31a, the abnormality determination module 31c determines a timing at which the discharge state has changed, and also performs determination on normality/abnormality regarding the substrate processing based on whether this timing is appropriate.

In the present exemplary embodiment, the information processing device 3 controls the substrate processing by the substrate processing apparatus 1. For example, the information processing device 3 controls a start and a stop of the discharge of the liquid from the discharger 13 by sending the substrate processing apparatus a command to open or close a valve provided in the liquid supply path from the liquid supply source 16 to the discharger 13. The abnormality determination module 31c calculates, based on the plurality of time-series determination results by the discharge state determination module 31b, a time from when the command to close the valve is given to the substrate processing apparatus 1 until a liquid column being discharged from the discharger 13 is broken. In this case, the abnormality determination module 31c specifies a timing at which the discharge state has changed from, for example, “liquid column present” to “liquid column broken and falling,” and calculates a time from when the command to close the valve is given to this timing. The abnormality determination module 31c makes a determination that an abnormality has occurred in the liquid discharge in the substrate processing when the calculated time exceeds a preset threshold value (e.g., 0.6 seconds to 0.8 seconds).

Also, the abnormality determination module 31c calculates a time from when the liquid discharge by the discharger 13 is stopped until the last droplet of the liquid falls. In this case, the abnormality determination module 31c specifies, for example, a first timing at which the discharge state has changed from “liquid column present” to “liquid column broken and falling” and a second timing at which the discharge state has changed from “liquid column broken and falling” to “no liquid present,” and calculates a time from the first timing to the second timing. However, if the discharge state changes from “liquid column broken and falling” to “no liquid present” and then further changes to, for example, “droplet present” within a preset time, the abnormality determination module 31c sets a timing at which this droplet has fallen and the discharge state has changed to “no liquid present” again as the second timing. The abnormality determination module 31c makes a determination that an abnormality has occurred in the liquid discharge in the substrate processing when the calculated time exceeds a preset threshold value (e.g., several seconds to several tens of seconds).

Further, the abnormality determination module 31c may perform the abnormality determination by other methods. By example, the abnormality determination module 31c may make a determination that there is an abnormality when the discharge state of “droplet present” occurs. As another example, the abnormality determination module 31c may calculate the size of the droplet in the frame image determined to show the discharge state of “droplet present,” and makes a determination that there is an abnormality when the calculated droplet size exceeds a threshold value. As still another example, the abnormality determination module 31c may make a determination that there is an abnormality when the number of times a droplet occurs exceeds a threshold value.

The display processor 31d performs a processing of displaying various characters, images, and the like on the display 34. In the present exemplary embodiment, when the abnormality determination module 31c makes a determination that there is an abnormality, the display processor 31d displays a warning screen for the user on the display 34 to notify the user of the occurrence of the abnormality. The display processor 31d displays, by way of example, an image (moving image or frame image) that caused the determination indicating the occurrence of the abnormality, information related to the abnormality that has occurred, the identification information of the processing target substrate, and the like, on the warning screen. Further, the display processor 31d may also display various other information on the display 34.

The control processor 31e performs a control for the liquid discharge performed in the substrate processing of the substrate processing apparatus 1 based on the determination result of the discharge state by the discharge state determination module 31b, the abnormality determination result by the abnormality determination module 31c, and the like. In the present exemplary embodiment, a valve is provided in the liquid supply path from the liquid supply source 16 to the discharger 13 in the substrate processing apparatus 1, and the control processor 31e may control the liquid discharge by the discharger 13 by sending a command to open or close this valve to the substrate processing apparatus 1. The control of the valve may be, for example, only a control of opening or closing it, or may be, for example, a control of adjusting an opening/closing amount or an opening/closing speed. In case of a configuration in which it is possible to selectively discharge the chemical liquid or the cleaning liquid from the single discharger 13, the control processor 31e may perform a switching control of determining which liquid is to be discharged.

By way of example, when the abnormality determination module 31c makes a determination that there is an abnormality, the control processor 31e performs a control of closing the valve, thereby stopping the liquid discharge by the discharger 13. In this case, the control processor 31e may discharge, for example, a cleaning liquid from the discharger 13. Also, when a time from when the control of closing the valve is performed until the liquid column discharged from the discharger 13 is broken is long over a threshold value, the control processor 31e may perform a control of increasing the speed of closing the valve.

The determination of the discharge state of the discharger 13 may be used in a preparation stage such as start-up of the substrate processing apparatus, rather than when the substrate processing is actually being performed. In this case, the control processor 31e may perform a control of gradually opening/closing the valve while adjusting an opening degree thereof, to thereby search for an opening degree of the valve at which a droplet occur. Also, the control processor 31e may perform a control of repeatedly performing the opening/closing operations of the valve while adjusting an opening/closing speed thereof, to thereby search for a speed at which a droplet occurs, a speed at which the time until the liquid column is broken exceeds the threshold value, and the like. Based on the information obtained by such a searching operation, the user may determine appropriate setting values for the substrate processing apparatus 1 to perform the substrate processing appropriately.

### <Discharge State Determination and Abnormality Determination>

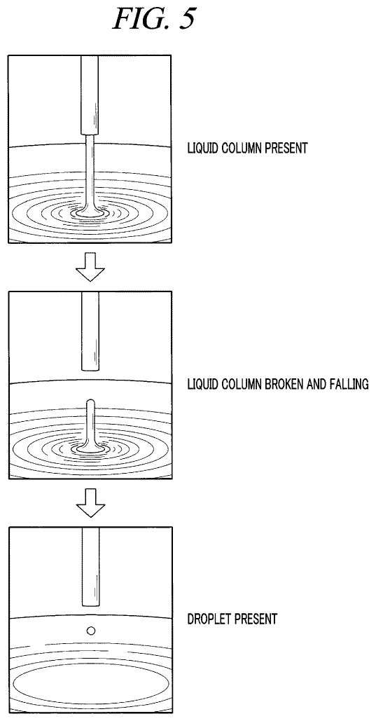

The information processing device 3 according to the present exemplary embodiment determines the discharge state of the liquid such as the chemical liquid or the cleaning liquid by the discharger 13 based on the moving image of the discharger 13 of the substrate processing apparatus 1 obtained by the camera 5. In the present exemplary embodiment, there are four types of discharge states: “liquid column present,” “liquid column broken and falling,” “droplet present,” and “no liquid present.” FIG. 5 is a schematic diagram illustrating examples of a discharge state. FIG. 5 shows an example of an image of the discharger 13 captured by the camera 5, where the upper image corresponds to the discharge state of “liquid column present,” the middle image corresponds to the discharge state of “liquid column broken and falling,” and the lower image corresponds to the discharge state of “droplet present.” Illustration of the discharge state of “no liquid present” is omitted.

In the present exemplary embodiment, the discharger 13 has a cylindrical shape and is disposed above the processing target substrate at a preset distance therebetween. The liquid such as the chemical liquid or the cleaning liquid is discharged from an opening at a lower end of the discharger 13, and the discharged liquid falls onto a top surface of the processing target substrate. The imaging range of the camera 5 is defined so as to include the range from the lower end of the discharger 13 to the top surface of the substrate. The discharger 13 is movable horizontally by a non-illustrated driving mechanism, and the camera 5 is configured to move as the discharger 13 moves or to image the entire movement range of the discharger 13, thus capable of imaging the discharger 13 discharging the liquid, regardless of the position of the discharger 13.

The discharge state of “liquid column present” is a state in which the liquid is being continuously discharged from the discharger 13 and the lower end of the discharger 13 and the top surface of the substrate are connected by a columnar liquid (liquid column). The discharge state of “liquid column broken and falling” is a state immediately after the discharge of the liquid from the discharger 13 is stopped, and in this state, there is a space between the lower end of the discharger 13 and an upper end of the liquid column, and the liquid column stands on the top surface of the substrate. The discharge state of “droplet present” is a state in which no liquid column exists between the lower end of the discharger 13 and the top surface of the substrate, and one or more spherical liquids (droplets) are present. The discharge state of “no liquid present” is a state in which neither the liquid column nor the droplet is present between the lower end of the discharger 13 and the top surface of the substrate.

The information processing device 3 according to the present exemplary embodiment acquires the moving image obtained by the camera 5, extracts the frame image included in the moving image, inputs the extracted frame image into the learning model shown in FIG. 4, and acquires information related to the discharge state output by the learning model. Based on the information acquired from the learning model, the information processing device 3 determines whether the discharge state of the discharger 13 shown in the frame image is “liquid column present,” “liquid column broken and falling,” “droplet present,” or “no liquid present”.

The moving image obtained by the camera 5 includes, for example, several tens of frame images per second, and the information processing device 3 repeatedly performs in time series the determination of the discharge state using the learning model for the plurality of frame images included in the moving image. As a result, the information processing device 3 can obtain, for example, several tens of determination results of the discharge state per second. Based on these time-series determination results of the discharge state, the information processing device 3 is capable of determining, for example, a timing at which the discharge state changes from “liquid column present” to “liquid column broken and falling,” a timing at which the discharge state changes from “liquid column broken and falling” to “no liquid present,” and the like. Further, the information processing device 3 is also capable of calculating a time during which a certain discharge state is maintained based on the timing at which the discharge state changes. By way of example, the information processing device 3 may calculate a time during which the discharge state of “liquid column broken and falling” is maintained based on the number of frames of the moving image existing between the timing at which the discharge state changes from “liquid column present” to “liquid column broken and falling” and the timing at which the discharge state changes from “liquid column broken and falling” to “no liquid present.”

Further, the information processing device 3 according to the present exemplary embodiment controls the start and the stop of the liquid discharge from the discharger 13 of the substrate processing apparatus 1 by providing the substrate processing apparatus 1 with the command to open or close the valve provided in the liquid supply path from the liquid supply source 16 to the discharger 13. For example, based on a timing at which the command to close the valve is given to the substrate processing apparatus 1 and the above-described timing determined from the image obtained by the camera 5, the information processing device 3 can calculate an elapsed time between the two timings.

Based on whether the time calculated in this way from the moving image obtained by the camera 5 exceeds a threshold value, the information processing device 3 determines presence or absence of the abnormality related to the liquid discharge of the substrate processing performed by the substrate processing apparatus 1. To determine the presence or absence of the abnormality, the information processing device 3 according to the present exemplary embodiment performs determinations of two conditions: whether a time from when the command to close the valve is given until the liquid column is broken exceeds a threshold value, and whether a time from when the liquid column is broken until the liquid discharge is ended exceeds a threshold value.

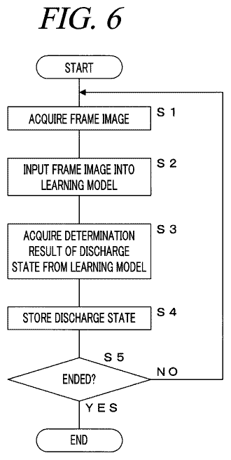

FIG. 6 is a flowchart showing an example sequence of a discharge state determination processing performed by the information processing device 3 according to the present exemplary embodiment. The discharge state determination module 31b of the processor 31 of the information processing device 3 according to the present exemplary embodiment acquires, among the plurality of frame images included in the moving image obtained by the camera 5, one oldest frame image in time series yet to be subjected to the determination of the discharge state (process S1). The discharge state determination module 31b inputs the frame image acquired in the process S1 into the machine learning-trained learning model (learning model shown in FIG. 4) stored in advance in the model information storage 32b (process S2). The discharge state determination module 31b acquires the determination result of the discharge state output by the learning model according to the image input in the process S2 (process S3).

The discharge state determination module 31b stores the discharge state acquired in the process S3 in the log information storage 32c together with the frame image acquired in the process S1, and various types of information such as the date and time when the frame image is acquired and the identification information of the processing target substrate (process S4). The discharge state determination module 31b determines whether the substrate processing by the substrate processing apparatus 1 has ended (process S5). If the substrate processing has not ended yet (S5: NO), the discharge state determination module 31b returns to the process S1 and performs the same processing for the next frame image in time series. If the substrate processing has ended (S5: YES), the discharge state determination module 31b ends the discharge state determination processing.

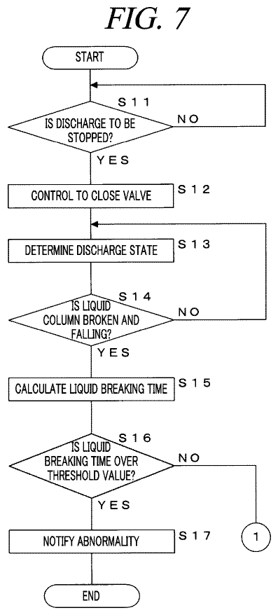

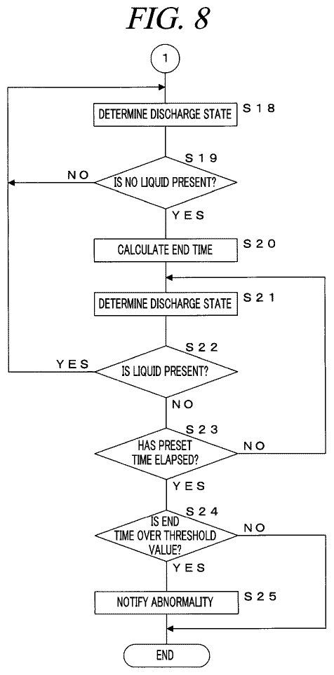

FIG. 7 and FIG. 8 are flowcharts showing an example sequence of an abnormality determination processing performed by the information processing device 3 according to the present exemplary embodiment. The processing shown in this flowchart starts when the substrate processing apparatus 1 discharges the liquid such as the chemical liquid or the cleaning liquid from the discharger 13. The information processing device 3 controls the substrate processing of the substrate processing apparatus 1 according to a previously set sequence and stops the discharge of the liquid by providing a command to stop the discharge to the substrate processing apparatus 1 after the liquid is discharged for a time or in an amount set as the sequence, for example. The abnormality determination module 31c of the processor 31 of the information processing device 3 according to the present exemplary embodiment determines whether a timing for stopping the liquid discharge by the discharger 13 of the substrate processing apparatus 1 has been reached (process S11). If the timing to stop has not arrived (S11: NO), the abnormality determination module 31c stands by until the timing to stop the liquid discharge arrives.

If the timing to stop the liquid discharge has been reached (S11: YES), the control processor 31e of the processor 31 performs a valve closing control by providing the substrate processing apparatus 1 with a command to close the valve provided in the liquid supply path from the liquid supply source 16 to the discharger 13 (process S12). Also, the abnormality determination module 31c determines the discharge state of the liquid from the discharger 13 based on the moving image obtained by the camera 5 (process S13). In the process S13, the processing of the flowchart shown in FIG. 6 is performed. Based on the determination result of the process S13, the abnormality determination module 31c determines whether the discharge state of the discharger 13 is “liquid column broken and falling” (process S14). If the discharge state is not “liquid column broken and falling” (S14: NO), the abnormality determination module 31c returns to the process S13 and repeats the determination of the discharge state.

If the discharge state is “liquid column broken and falling” (S14: YES), the abnormality determination module 31c calculates a time (liquid breaking time) from the timing at which the command to close the valve is given in the process S12 to the timing at which it is determined that the discharge state is “liquid column broken and falling” in the process S14 (process S15). The abnormality determination module 31c determines whether the liquid breaking time calculated in the process S15 exceeds a preset threshold value (process S16). If the liquid breaking time exceeds the threshold value (S16: YES), the display processor 31d of the processor 31 displays a warning screen on the display 34 to notify the user of the abnormality (process S17) and ends the processing.

If the liquid breaking time does not exceed the threshold value (S16: NO), the abnormality determination module 31c determines the discharge state of the liquid from the discharger 13 based on the moving image obtained by the camera 5 (process S18). Based on the determination result of the process S18, the abnormality determination module 31c determines whether the discharge state of the discharger 13 is “no liquid present” (process S19). If the discharge state is not “no liquid present” (S19: NO), the abnormality determination module 31c returns to the process S18 and repeats the determination of the discharge state. If the discharge state is “no liquid present” (S19: YES), on the other hand, the abnormality determination module 31c calculates a time (end time) from the timing at which it is determined that the discharge state is “liquid column broken and falling” in the process S14 to the timing at which it is determined that the discharge state is “no liquid present” in the process S19 (process S20).

Subsequently, the abnormality determination module 31c determines the discharge state of the liquid from the discharger 13 based on the moving image obtained by the camera 5 (process S21). Based on the determination result of the process S21, the abnormality determination module 31c determines whether the discharge state of the discharger 13 is “droplet present” (process S22). If the discharge state is “droplet present” (S22: YES), the abnormality determination module 31c returns to the process S18 and repeats the determination of the discharge state. If the discharge state is not “droplet present” (S22: NO), on the other hand, the abnormality determination module 31c determines whether a set time has elapsed from the timing when it is determined that the discharge state is “no liquid present” in the process S19 (process S23). If the set time has not passed by (S23: NO), the abnormality determination module 31c returns to the process S21 and repeats the determination of the discharge state.

If the set time has elapsed (S23: YES), the abnormality determination module 31c determines whether the end time calculated in the process S20 exceeds a set threshold value (process S24). If the end time exceeds the threshold value (S24: YES), the display processor 31d displays a warning screen on the display 34 to notify the user of the abnormality (process S25) and ends the processing. If the end time does not exceed the threshold value (S24: NO), the abnormality determination module 31c does not perform abnormality notification through the display of the warning screen and ends the processing.

### <Display Processing>

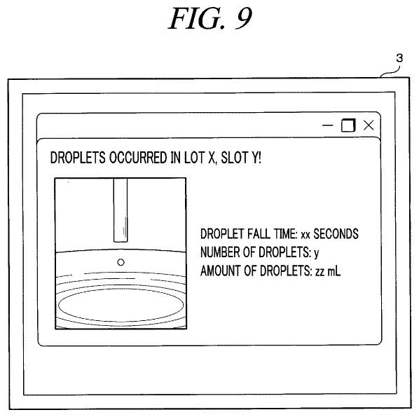

FIG. 9 is a schematic diagram showing an example of a warning screen displayed by the information processing device 3 according to the present exemplary embodiment. The information processing device 3 according to the present exemplary embodiment displays a warning screen on the display 34 in the processes S17 and S25 of the above-described flowchart, for example. The warning screen shown in FIG. 9 is an example of a warning screen displayed in the process S25 when it is determined that droplets have been formed and the end time has exceeded the threshold value. The information processing device 3 acquires identification information such as a lot number, a slot number, and the like assigned to the substrate as the target of the substrate processing and displays a warning message such as “Droplets occurred in Lot X, slot Y!” in an upper portion of this warning screen. The identification information of the substrate as the target of the substrate processing may be input by the user into the information processing device 3 or the substrate processing apparatus 1 before the start of the substrate processing, for example.

Further, the information processing device 3 also displays, below the warning message on the warning screen, one of the frame images when the discharge state is determined to be “droplet present” or a moving image including the multiple frame images where the discharge state is found to be “droplet present.” The information processing device 3 also displays information of “Droplet fall time: xx seconds” based on the end time calculated in the process S20 of the above-described flowchart. Furthermore, the information processing device 3 may count the number of droplets and display information of “Number of droplets: y,” and may display information of “Amount of droplets: zz mL” based on the size of the droplets. The calculation of the number and the amount of the droplets is omitted in the flowcharts of FIG. 6 to FIG. 8.

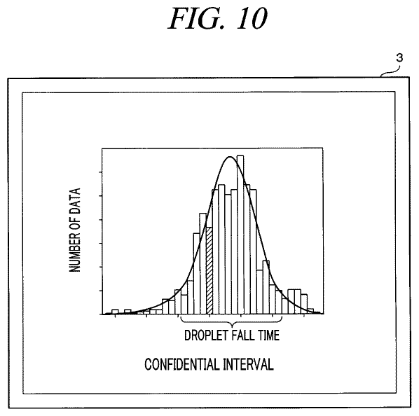

FIG. 10 is a schematic diagram showing an example of information display by the information processing device 3 according to the present exemplary embodiment. The information processing device 3 according to the present exemplary embodiment may display information on the occurrence of the droplets, separately from the aforementioned warning screen (or together with the warning screen). The information processing device 3 stores, for example, the droplet fall time when the droplets occur (the end time of the process S20) in the log information storage 32c. The information processing device 3 reads out multiple values of the past droplet fall time stored in the log information storage 32c and displays on the display 34 a histogram with the droplet fall time on the horizontal axis and the number of data on the vertical axis.

The information processing device 3 indicates which part of the histogram the latest droplet fall time belongs to by highlighting the corresponding part by, for example, color-coding. The information processing device 3 also displays a distribution curve superimposed on the histogram of the droplet fall time, assuming that the distribution of the droplet fall time follows a normal distribution, for example. Also, the information processing device 3 calculates a set confidence interval for the distribution of the droplet fall time and indicates on the histogram the range of the droplet fall time corresponding to the calculated confidence interval. The information processing device 3 may determine, for example, the threshold value used for the determination in the process S24 of the above-described flowchart based on an upper limit of the confidence interval for the distribution of the past droplet fall time. The information processing device 3 may periodically calculate the set confidence interval based on the information of the multiple values of the past droplet fall time stored in the log information storage 32c and periodically update the threshold value used for the determination.

The displays on the screen shown in FIG. 9 and FIG. 10 is merely an example and is not anyway limiting, and the information processing device 3 may notify an abnormality occurring in the substrate processing in any of various display forms. Furthermore, the information processing device 3 may display these information not only when an abnormality occurs but also when no abnormality occurs.

### Modification Examples

### First Modification Example

In the information processing system according to a first modification example, a second camera configured to image a surface of the processing target substrate is provided in the chamber 11 of the substrate processing apparatus 1, in addition to the camera 5 configured to image the discharger 13. The information processing device 3 acquires data of a moving image obtained by the second camera and determines dryness (whether dry or wet) of the substrate based on a frame image included in the acquired moving image.

To determine the dryness of the substrate surface, a learning model that has been generated in advance by machine learning may be used, for example. The learning model for determining the dryness may be generated by performing so-called supervised machine learning, using training data (labeled data) in which an image of the substrate surface and a flag indicating whether the substrate surface in the image is dry or wet are matched. However, the determination on the dryness of the substrate surface may also be carried out by a method that does not use such a learning model, for example, by a method that makes the determination based on a comparison between a pixel value of the image of the substrate surface and a threshold value.

The information processing device 3 according to the first modification example performs both the determination of the discharge state based on the frame images included in the moving image of the discharger 13 and the determination of the dryness based on the frame image included in the moving image of the substrate surface. By way of example, when it is determined that the discharge state is “droplet present” and that the substrate surface is dry, the information processing device 3 may make a determination that an abnormality has occurred in the discharge of the liquid in the substrate processing and may notify the user.

The aforementioned conditions for the abnormality determination are merely examples and are not limiting. The information processing device 3 may perform any notification and control for any combination of the determination results of the liquid discharge state and the determination results of the dryness of the substrate surface. Also, instead of providing the camera for imaging the substrate surface separately from the camera 5 for imaging the discharger 13, the camera 5 may be configured to image both the discharger 13 and the substrate surface.

### Second Modification Example

In the above-described exemplary embodiment, it is determined whether there is an abnormality when the substrate processing apparatus 1 stops the discharge of the liquid from the discharger 13, but the present disclosure is not limited thereto. The information processing device 3 according to the second modification example determines whether there is an abnormality when the substrate processing apparatus 1 starts the discharge of the liquid from the discharger 13. The information processing device 3 according to the second modification example makes a determination that an abnormality has occurred when a droplet is discharged from the discharger 13 between a time when a command to open the valve to discharge the liquid from the discharger 13 is given and a time when a column of the liquid (liquid column) is discharged from the discharger 13, and displays a warning screen or performs a control processing in response to the abnormality.

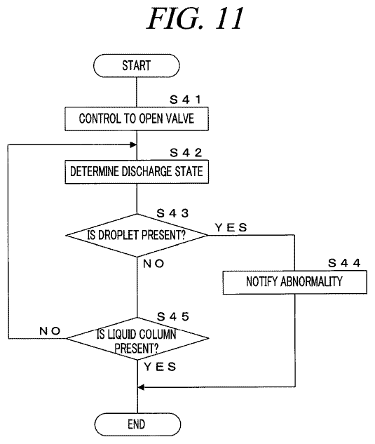

FIG. 11 is a flowchart showing an example sequence of an abnormality determination processing performed by the information processing device 3 according to the second modification example. The control processor 31e of the processor 31 of the information processing device 3 according to the second modification example performs a control of opening the valve provided in the liquid supply path from the liquid supply source 16 to the discharger 13 by communicating with the substrate processing apparatus 1 through the communication module 33 (process S41).

Thereafter, the abnormality determination module 31c of the processor 31 determines the discharge state of the liquid from the discharger 13 based on the moving image obtained by the camera 5 (process S42). The abnormality determination module 31c determines whether the discharge state of the discharger 13 is “droplet present” based on the determination result of the process S42 (process S43). If the discharge state is found to be “droplet present” (S43: YES), the abnormality determination module 31c notifies the user of the abnormality by displaying a warning screen on the display 34 (process S44) and ends the processing.

If the discharge state is not “droplet present” (S43: NO), the abnormality determination module 31c determines whether the discharge state of the discharger 13 is “liquid column present” based on the determination result of the process S42 (process S45). If the discharge state is not “liquid column present” (S45: NO), the abnormality determination module 31c returns to the process S42, and repeats the determination of the discharge state. If the discharge state is found to be “liquid column present” (S45: YES), the abnormality determination module 31c ends the abnormality determination processing when the discharge is started.

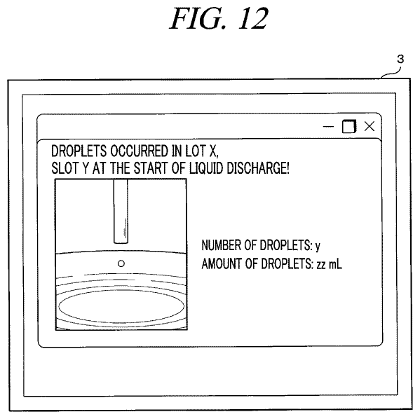

FIG. 12 is a schematic diagram showing one example of a warning screen displayed by the information processing device 3 according to the second modification example. The information processing device 3 according to the second modification example displays a warning screen on the display 34 in the process S44 of the above-described flowchart, for example. The information processing device 3 acquires identification information such as a lot number and a slot number assigned to the substrate as the target of the substrate processing, and displays a warning message such as “Droplets occurred in Lot X, slot Y when the discharge is started!” at an upper portion of the warning screen shown in FIG. 12. In addition, the information processing device 3 displays, below this warning message on the warning screen, one of the frame images when the discharge state is determined to be “droplet present” or a moving image including the multiple frame images where the discharge state is found to be “droplet present.” The information processing device 3 may also count the number of droplets and display information of “Number of droplets: y,” and may display the information of “Amount of droplets: zz mL” based on the size of the droplets.

### <Summary>

In the information processing system according to the present exemplary embodiment having the above-described configuration, the information processing device 3 acquires the moving image of the discharger 13 of the substrate processing apparatus 1 discharging the liquid onto the processing target substrate. The information processing device 3 inputs the frame image included in the acquired moving image into the learning model that has been machine learning-trained in advance to receive the image of the discharger 13 as the input and output the information related to the discharge state of the liquid from the discharger 13. The information processing device 3 acquires the information output by the learning model and determines whether the discharge of the liquid in the substrate processing is appropriate (normal/abnormal) based on the acquired information. In this way, in the information processing system according to the present exemplary embodiment, the information processing device 3 can automatically determine whether the discharge of the liquid is appropriate or not based on the moving image obtained by the camera 5.

In addition, in the information processing system according to the present exemplary embodiment, the discharge states determined by the information processing device 3 include the first state of “liquid column present” in which the liquid is being discharged in the column shape from the discharger 13 onto the substrate as the processing target, the second state of “liquid column broken and falling” in which the liquid discharged from the discharger 13 has broken and the liquid column is falling onto the substrate, the third state of “droplet present” in which droplets are falling from the discharger 13 onto the substrate, and the fourth state of “no liquid present” in which no liquid is being discharged from the discharger 13. In this way, the information processing system according to the present exemplary embodiment can make the accurate determinations regarding the discharge of the liquid by using the learning model that has learned these discharge states.

Further, in the information processing system according to the present exemplary embodiment, the information processing device 3 calculates the time from the point when it has performed the control of stopping the discharge of the liquid by the discharger 13 to the point when the discharge state of the liquid has changed from “liquid column present” to “liquid column broken and falling” based on the information obtained from the learning model, and determines whether the discharge of the liquid in the substrate processing is normal or abnormal based on the calculated time. The information processing device 3 stops the discharge of the liquid by performing the control of closing the valve provided in the flow path from the liquid supply source 16 to the discharger 13. In this way, the information processing system according to the present exemplary embodiment can make the determination that there is the abnormality when the discharge of the liquid is not stopped even after the lapse of the preset time after the discharge of the liquid is stopped.

Further, in the information processing system according to the present exemplary embodiment, the information processing device 3 determines whether the discharge of the liquid in the substrate processing is normal/abnormal based on whether the information acquired from the learning model is “droplet present.” In this way, the information processing system according to the present exemplary embodiment can determine whether the substrate processing is appropriate based on whether the droplet has occurred. Moreover, the information processing device 3 may further calculate the size of the droplets and make the determination on whether the substrate processing is normal/abnormal based on the calculated size.

Besides, in the information processing system according to the present exemplary embodiment, the information processing device 3 calculates the time taken for the information acquired from the learning model to change from “liquid column broken and falling” to “no liquid present” and determines whether the discharge of the liquid in the substrate processing is normal or abnormal based on the calculated time. In this way, the information processing system according to the present exemplary embodiment can accurately determine the abnormality based on the time taken for the discharge of the liquid to be stopped.

Additionally, in the information processing system according to the present exemplary embodiment, the information processing device 3 controls the opening and closing of the valve provided in the flow path from the liquid supply source 16 to the discharger 13 based on the information acquired from the learning model, thereby controlling the discharge of the liquid from the discharger 13. By way of example, when it is determined that there is the abnormality based on the information acquired from the learning model, the information processing device 3 may perform the control such as stopping the discharge of the liquid from the discharger 13. With this configuration, the information processing system according to the present exemplary embodiment can perform the accurate control over the discharge of the liquid in the substrate processing.

In addition, in the information processing system according to the present exemplary embodiment, when it is determined that the discharge of the liquid in the substrate processing is not appropriate, the information processing device 3 notifies the user of the abnormality by displaying the warning screen on the display 34, for example. In this case, the information processing device 3 may notify the user of, by way of example, presence or absence of the droplets, the number of the droplets, the amount of the droplets, the droplet fall time, and the like, and may also notify the user of, for example, the identification information assigned to the substrate as the processing target. In this way, the information processing system according to the present exemplary embodiment can notify the user of the presence or absence of the abnormality in the discharge of the liquid in the substrate processing and of the related information in the event of the abnormality, thereby encouraging the user to take action to deal with the abnormality.

Further, in the information processing system according to the present exemplary embodiment, the information processing device 3 stores in the log information storage 32c at least the frame image and the information acquired from the learning model when it is determined that the discharge of the liquid is not appropriate. The information processing device 3 may or may not store in the log information storage 32c information when it is determined that the discharge of the liquid is appropriate. In this way, the information processing system according to the present exemplary embodiment can enable the user to verify the cause, etc., of the abnormality when it occurs, based on the information stored in the log information storage 32c.

In addition, in the information processing system according to the present exemplary embodiment, the information processing device 3 acquires the moving image of the processing target substrate, determines the surface state of the substrate based on the frame images included in the acquired moving image, and determines whether the discharge of the liquid in the substrate processing is normal or abnormal based on the information on the discharge state acquired from the learning model and the determined surface state of the substrate. The surface state of the substrate includes, for example, the state in which the substrate surface is dry and the state in which the substrate surface is wet. In this way, the information processing system according to the present exemplary embodiment can accurately perform the abnormality determination by taking the surface state of the processing target substrate into account.

In addition, in the information processing system according to the present exemplary embodiment, the information processing device 3 determines whether the discharge of the liquid in the substrate processing is normal or abnormal based on whether the discharge state of “droplet present” has occurred during the time period from when the control of starting the discharge of the liquid by the discharger 13 is performed until the discharge state becomes “liquid column present.” In this way, the information processing system according to the present exemplary embodiment can perform the abnormality determination not only when the discharge of the liquid from the discharger 13 is stopped but also when the discharge of the liquid is started.

The exemplary embodiments disclosed herein should be considered to be illustrative in all aspects and not anyway limiting. The scope of the present disclosure is defined by the scope of the claims, not by the meaning described above, and is intended to include all modifications within the scope and meaning equivalent to the scope of the claims.

The matters described in the exemplary embodiments can be combined with each other. In addition, it is to be understood that any combination of features described in the independent and dependent claims may be made, regardless of the manner in which the claims are referenced. In addition, although the claims are described using a format (multiple dependent claim format) in which a claim refers to two or more other claims, the present disclosure is not limited thereto. A format (multiple-multiple dependent claim format) may also be employed in which a multiple dependent claim depends on at least one other multiple dependent claim.

According to the exemplary embodiment, an information processing apparatus can determine the state related to the discharge of the liquid such as the chemical liquid or the cleaning liquid in the substrate processing.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A computer-readable recording medium having stored thereon a computer program that, in response to execution, causes a computer to perform a method, the method comprising:
acquiring a moving image of a discharger of a substrate processing apparatus configured to discharge a liquid to a substrate as a processing target;
inputting a frame image included in the acquired moving image into a learning model that has been machine learning-trained to receive an image of the discharger as an input and output information related to a discharge state of the liquid from the discharger;
acquiring the information related to the discharge state output by the learning model; and
determining appropriateness of the discharge of the liquid based on the acquired information.

2. The computer-readable recording medium of claim 1, wherein the discharge state includes one from among:
a first state in which the liquid is being discharged in a column shape from the discharger onto the substrate as the processing target;
a second state in which the liquid discharged from the discharger is broken and the liquid of the column shape is falling onto the substrate;
a third state in which a droplet is falling from the discharger onto the substrate; and
a fourth state in which no liquid is being discharged from the discharger.

3. The computer-readable recording medium of claim 2, wherein the method further comprises:
calculating a time from a timepoint when a stop control of stopping the discharge of the liquid by the discharger is performed to a timepoint when the discharge state of the liquid is changed from the first state to the second state based on the information acquired from the learning model, and
determining the appropriateness of the discharge of the liquid based on the calculated time.

4. The computer-readable recording medium of claim 3, wherein the method further comprises:
controlling opening/closing of a valve provided in a flow path of the liquid, and
performing a control of closing the valve as the stop control.

5. The computer-readable recording medium of claim 2, wherein the appropriateness of the discharge of the liquid is determined based on whether the discharge state of the liquid is the third state on the basis of the information acquired from the learning model.

6. The computer-readable recording medium of claim 5, wherein the method further comprises:
when the discharge state of the liquid is determined to be the third state, calculating a size of a droplet, and
determining the appropriateness of the discharge of the liquid based on the calculated size.

7. The computer-readable recording medium of claim 2, wherein the method further comprises:
calculating a time taken for the discharge state of the liquid to be changed from the second state to the fourth state based on the information acquired from the learning model, and
determining the appropriateness of the discharge of the liquid based on the calculated time.

8. The computer-readable recording medium of claim 1, wherein the method further comprises controlling opening/closing of a valve provided in a flow path of the liquid based on the information acquired from the learning model.

9. The computer-readable recording medium of claim 1, wherein the method further comprises making a notification when the discharge of the liquid is determined to be inappropriate.

10. The computer-readable recording medium of claim 9, wherein the notification includes presence or absence of a droplet, a number of droplets, an amount of the droplets, or a falling time of the droplets.

11. The computer-readable recording medium of claim 9, wherein the notification includes identification information assigned to the substrate as the processing target.

12. The computer-readable recording medium of claim 1, wherein the method further comprises storing the frame image and the information acquired from the learning model when the discharge of the liquid is determined to be inappropriate in a storage.

13. The computer-readable recording medium of claim 1, wherein the method further comprises:
acquiring a moving image of the substrate as the processing target;
determining a surface state of the substrate based on a frame image included in the acquired moving image; and
determining the appropriateness of the discharge of the liquid based on the information related to the discharge state output from the learning model and the determined surface state of the substrate.

14. The computer-readable recording medium of claim 13, wherein the surface state includes one from among:
a state in which a surface of the substrate is dry; and
a state in which the surface of the substrate is wet.

15. The computer-readable recording medium of claim 2, wherein the appropriateness of the discharge of the liquid is determined based on whether the third state occurs during a period until the discharge state of the liquid becomes the first state after a control of starting the discharge of the liquid by the discharger is performed.

16. The computer-readable recording medium of claim 1, wherein the method further comprises controlling opening/closing of a valve provided in a flow path of the liquid based on the appropriateness of the discharge of the liquid.

17. An information processing method performed by an information processing device, the method comprising:
acquiring a moving image of a discharger of a substrate processing apparatus configured to discharge a liquid to a substrate as a processing target;
inputting a frame image included in the acquired moving image into a learning model that has been machine learning-trained to receive an image of the discharger as an input and output information related to a discharge state of the liquid from the discharger;
acquiring the information related to the discharge state output from the learning model; and
determining appropriateness of the discharge of the liquid based on the acquired information.

18. The information processing method of claim 17, further comprising controlling opening/closing of a valve provided in a flow path of the liquid based on the appropriateness of the discharge of the liquid.

19. An information processing device, comprising:
one or more processor configured to:
acquire a moving image of a discharger of a substrate processing apparatus configured to discharge a liquid to a substrate as a processing target;
input a frame image included in the acquired moving image into a learning model that has been machine learning-trained to receive an image of the discharger as an input and output information related to a discharge state of the liquid from the discharger;
acquire information related to the discharge state output from the learning model; and
determine appropriateness of the discharge of the liquid based on the acquired information.

20. The information processing device of claim 19, wherein the one or more processor is configured to control opening/closing of a valve provided in a flow path of the liquid based on the appropriateness of the discharge of the liquid.
